(19) United States
(12) Patent Application Publication
(10) Pub. No.: US 2008/0217162 A1
(43) Pub. Date: Sep. 11, 2008

(54) Method to Deposit a Coating By Sputtering

(75) Inventors: Hilde Delrue, Mont-de-IEnclus (BE); Jurgen Denul, Deinze (BE); Anneke Segers, Gent (BE)

Correspondence Address: FOLEY AND LARDNER LLP;SUITE 500, 3000 K STREET NW, WASHINGTON, DC, 20007, US

(73) Assignee: NV BEKAERT SA

(21) Appl. No.: 12/088,551

(22) PCT Filed: Sep. 27, 2006
(86) PCT No.: PCT/EP2006/066776

§ 371 Date: Mar. 28, 2008

(30) Foreign Application Priority Data
Oct. 13, 2005 (EP) 05109518.0

(51) Int. Cl. C23C 14/34

(52) U.S. Cl. 204/192.15; 204/298.13

(57) ABSTRACT

The invention relates to a method to deposit a coating on a substrate by sputtering using a sputter target comprising a doping element whereby the deposited coating is substantially free of the doping element. The invention further relates to a sputter target having as sputter material a non-conductive main component and a semiconductive or conductive doping element.

### FIELD OF THE INVENTION

The invention relates to a method to deposit a coating on a substrate by sputtering using a sputter target comprising a doping element whereby the deposited coating is substantially free of said doping element.

The invention further relates to a sputter target having as sputter material a non-conductive main component and a semiconductive or conductive doping element.

### BACKGROUND OF THE INVENTION

To deposit thin ceramic layers by means of sputtering, there are roughly two ways: the first method comprises reactive sputtering from a metallic target; the second method comprises sputtering from a ceramic target. Both methods have some drawbacks.

Instabilities in the process, arcing, poisoning of the target and disappearing anode are well known phenomena associated with reactive sputtering processes.

Another drawback of reactive sputter processes is the oxidation of the metallic substrate that may occur at high temperatures due to the presence of oxygen. This problem occurs in particular in case of in situ heating during the reactive sputtering.

This can have negative implications on the quality of the deposited layer and on the interface quality between the substrate and the deposited layer. This is well known in processes such as epitaxial growth of biaxial textured buffer layers for high temperature superconductors in which oxidation of the substrate can destroy the texture.

A method to avoid these problems is to sputter from a ceramic target. However, due to the low electrical conductivity of the ceramic material, these targets cannot be used in a direct current (DC) sputtering process.

They can only be used in an RF sputtering process. RF power supplies presently available are not suitable for large area coating with high power. The limited heat conductivity of the ceramic also limits the maximum power density of a ceramic target. Since the deposition rate is linear dependent to the power density, the deposition speed during RF sputtering is low.

To increase both the electrical conductivity and the heat conductivity of a ceramic sputtering target, a doping element can be added to the sputter target. However, as the doping element will be incorporated in the deposited coating, it may have a negative effect on the properties of the coating.

### SUMMARY OF THE INVENTION

It is an object of the present invention to provide a method to deposit a coating on a substrate avoiding the problems of the prior art.

It is another object of the invention to provide a method to deposit a coating by sputtering from a sputter target comprising a doping element whereby the deposited coating is substantially free of this doping element.

It is a further object of invention to provide a sputter target suitable for direct current (DC) or pulsed DC sputtering.

According to a first aspect of the present invention a method to deposit a coating on a substrate by sputtering from a sputter target is provided.

The sputter target comprises as sputter material a main component and a doping element.

The substrate is heated during sputtering to obtain a deposited coating that is substantially free of the doping element.

The substrate is for example heated to a temperature higher than 200° C.

The method preferably comprises the sublimation and/or evaporation of the doping element during the sputter process or comprises the sublimation and/or evaporation of a reaction product of the doping element that is created during the sputter process. The reaction product of the doping element is for example the result of a reaction of the doping element with the sputter gas.

As the doping element is sublimated and/or evaporated during the sputter process, the deposited coating is substantially free of the doping element.

To avoid that the sublimated and/or evaporated product is incorporated in the deposited coating, it is preferred that the temperature of the substrate is higher than the sublimation and/or evaporation temperature of the doping element or the reaction product of the doping element. More preferably, the temperature of the substrate is also higher than the temperature of the deposition chamber. This can for example be realized by heating the substrate, by cooling the deposition chamber or by a combination of both.

In a preferred embodiment of the present invention, the substrate is heated to a temperature higher than 200° C. and more preferably to a temperature higher than 300° C., 400° C., 500° C., 600° C. or 700° C.

Sublimation is defined as the change of state of a substance from the solid state to the gaseous state without first becoming a liquid.

Evaporation is defined as the change of state of a substance from the liquid state to the gaseous state.

After sublimation and/or evaporation, the doping element or the reaction product of the doping element condenses, for example on the walls of the vacuum chamber or on cooling shields placed in the vacuum chamber.

The method is in particular of importance for sputter materials of a sputter target having as main component a component having no conductivity or having a low conductivity. By doping such a sputter material with an electrically conductive doping element, the sputter material is becoming electrically conductive so that the sputter target can be used for DC or pulsed DC sputtering.

As the deposited coating is substantially free of the doping element, the doping element will have no negative effect on the properties of the coating.

To be used in a DC sputtering process, the sputter material has preferably a resistivity lower than 6000 Ωm. More preferably, the sputter material of a sputter target according to the present invention has a resistivity lower than 1200 Ωm and most preferably the resistivity of the sputter material is lower than 120 Ωm.

To be used in a pulsed DC sputtering process, the resistivity is preferably lower than 15000 Ωm.

The doping element or a reaction product of this doping element created during the sputtering preferably has a low sublimation temperature and/or evaporation temperature in vacuum.

The sublimation and/or evaporation temperature in vacuum can be calculated via the Clausius-Clapeyron law:

Tₚ=T₀/(1+T₀*ln(p₀/p)/(L/k))

whereby
T₀ is the sublimation and/or evaporation temperature at standard pressure p₀;
k is the Boltzmann constant;
L is the latent heat vaporization per molecule.

Preferably, the doping element or the reaction product thereof has a sublimation and/or evaporation temperature lower than 700° C., more preferably the sublimation and/or evaporation temperature is lower than 600° C. or even lower than 500° C. as for example 400° C.

For the purpose of this invention, with ‘vacuum’ is meant that the pressure in the deposition chamber during sputtering is between 10⁻⁴ mbar and 10⁻¹ mbar.

The deposited coating is substantially free of the doping element. With ‘substantially free’ is meant that the concentration of the doping element is lower than 5 at % in the deposited coating. More preferably, the concentration is lower than 1 at % or even lower than 0.1 at % (i.e. lower than the detection limit of X-ray PhotoSpectrometry).

To selectively deposit the sublimated and/or evaporated doping element, it can be preferred to provide a plate or screen such as a cooled plate or screen in the deposition chamber.

This selectively deposition has as advantage that the doping element can be recovered more easily.

As main component of the sputter target any metal or metal alloy or any oxide, nitride or mixture of oxides and nitrides can be considered.

The method according to the present invention is in particular suitable for sputter targets having a target material with as main component a component having a low electrical conductivity such as ceramic materials as for example zirconium oxides, either stabilized or non stabilized. Zirconium oxide can for example be stabilized with yttrium, calcium or magnesium.

Other examples comprise cerium oxide (f.e. CeO₂), aluminium oxide (f.e. Al₂O₃), lithium cobalt oxide (f.e. LiCoO₂), chromium oxide (f.e. Cr₂O₃), indium oxide (In₂O₃), titanium oxide (f.e. TiO₂), LiPON, strontium barium titanate (SrBaTiO3), . . . .

Also sub- and superstoechiometric variants of these oxides can be considered.

As doping element in principle any element that is sublimating and/or evaporating in vacuum at a relatively low temperature or that is resulting in a reaction product during the sputter process that is sublimating and/or evaporating at a relatively low temperature and that is giving the sputter target the required electrical conductivity can be considered.

Preferably, the doping element comprises a metal. Preferred doping elements are silver, tin, zinc, bismuth and antimony.

In reactive sputter processes (for example processes in argon or oxygen atmosphere), silver and tin are preferred doping elements as both elements form oxides with low sublimation and/or evaporation temperature.

The concentration of the doping element is mainly determined by the electrical conductivity of the target that is required.

The higher the concentration of the doping element, the higher the electrical conductivity of the target will be.

Preferably, the concentration of the doping element is between 1 and 50 wt %, for example between 1 and 40 wt % or between 2 and 20 wt %, as for example 5, 10, 15 wt %.

In principle, the method according to the present invention can be used to deposit any type of coating.

Preferred coatings comprise ceramic coatings such as oxides, nitrides and oxynitrides.

Examples of coatings comprise zirconium oxides, such as YSZ (yttrium stabilized zirconium), cerium oxides, aluminium oxides, lithium cobalt oxides, chromium oxides, indium oxides and titanium oxides, SrBaTiO₃, . . . .

As the deposited coating is substantially free of the doping element, the properties of the coating are not influenced by the doping element.

According to a second aspect of the present invention, a sputter target is provided. The sputter target comprises a sputter material. This sputter material comprises a main component having no conductivity or a low conductivity and a doping element being semiconductive or conductive. The doping element is providing the sputter material the required electrical conductivity so that the sputter target can be used in a DC sputtering process.

The main component and the doping element are present in a concentration to give the sputter material a resistivity lower than 6000 Ωm.

More preferably, the sputter material of a sputter target according to the present invention has a resistivity lower than 1200 Ωm and most preferably the resistivity of the sputter material is lower than 120 Ωm.

The sputter target according to the present invention can be obtained by any technique known in the art, for example by spraying, sintering or pressing such as cold or hot isostatic pressing.

### DESCRIPTION OF THE PREFERRED EMBODIMENTS OF THE INVENTION

According to the present invention a planar 2 inch sputter target comprising zirconium oxide/yttrium oxide (88/12) doped with 20-30 wt % silver is provided.

The sputter target can be manufactured by any method known in the art. A preferred method to manufacture the sputter target is by spraying, e.g. flame or plasma spraying the target material on a target holder. Although the target holder of the sputter target mentioned in the example is planar, also cylindrical target holders can be considered. An adhesion promoting layer can be applied on the target holder before the application of the target material.

The target as described above is used in a DC sputter process (power 100 W) to deposit an YSZ coating on a MgO substrate. The substrate temperature was 700° C. The sputtering process was done with on O₂ flow between 0.6 and 2 sccm and an Ar flow of 130 sccm.

The pressure in the vacuum chamber was about 2.10⁻² mbar.

The concentration of the silver in the deposited coating was determined by means of X-ray PhotoSpectrometry. The concentration was below the detection limit.

Due to the high substrate temperature epitaxial layers of YSZ were grown.

Biaxial textured (200) YSZ layers could be deposited with a FWHM of 3.5°.

1. A method to deposit a coating on a substrate by sputtering from a sputter target, said sputter target comprising as sputter material a main component and a doping element, whereby said substrate is heated during sputtering to obtain a coating that is substantially free of said doping element.

2. A method according to claim 1, whereby said substrate is heated during sputtering to a temperature higher than 200° C.

3. A method according to claim 1, whereby said method comprises the sublimation and/or evaporation of said doping element or comprises the sublimation and/or evaporation of a reaction product of said doping element during the sputter process.

4. A method according to claim 1, whereby said substrate is heated during sputtering to a temperature higher than the sublimation and/or evaporation temperature of said doping element.

5. A method according to claim 1, whereby said sputtering is DC or pulsed DC sputtering.

6. A method according to claim 1, whereby said sputter material has a resistivity lower than 15000 Ωm.

7. A method according to claim 1, whereby said sputter material has a resistivity lower than 6000 Ωm.

8. A method according to claim 3, whereby said doping element or said reaction product of said doping element has in vacuum a sublimation temperature lower than 700° C.

9. A method according to claim 1, whereby said doping element is selected from the group consisting of silver, tin, zinc, bismuth and antimony.

10. A method according to claim 1, whereby said doping element is present in said sputter material in a concentration ranging between 1 and 50 wt %.

11. A method according to claim 1 any one of the preceding claims, whereby said main component is selected from the group consisting of metals, metal alloys, oxides, nitrides and mixtures thereof.

12. A method according to claim 1, whereby said main component is selected from the group consisting of cerium oxide, aluminium oxide, lithium cobalt oxide, chromium oxide, indium oxide, titanium oxide, LiPON and strontium barium titanate.

13. A sputter target comprising a sputter material, said sputter material comprising a main component having no conductivity or having a low conductivity and a doping element being semiconductive or conductive, said main component and said doping element being present in a concentration to give the sputter material a resistivity lower than 15000 Ωm, whereby said doping element or a reaction product of said doping element is sublimating and/or evaporating in vacuum when said sputter target is used in a sputtering process.

14. A sputter target according to claim 13, whereby said resistivity is lower than 6000 Ωm.

15. A sputter target according to claim 13, whereby said resistivity is lower than 1200 Ωm.

16. A sputter target according to claim 13, whereby said resistivity is lower than 120 Ωm.

17. A sputter target according to claim 13, whereby said sputter target is suitable to be used in a DC or pulsed DC sputtering process.

18. A sputter target according to claim 13, whereby said doping element or said reaction product of said doping element has in vacuum a sublimation temperature lower than 700° C.

19. A sputter target according to claim 13, whereby said doping element is selected from the group consisting of silver, gold, antimony, bismuth and tin.

20. A sputter target according to claim 13, whereby said doping element is present in said sputter material in a concentration ranging between 1 and 50 wt %.

21. A sputter target according to claim 13, whereby said main component is selected from the group consisting of metals, metal alloys, oxides, nitrides and mixtures thereof.

22. A sputter target according to claim 13, whereby said main component is selected from the group consisting of zirconium oxides, stabilized zirconium oxides, cerium oxides, aluminium oxides, lithium cobalt oxides, zinc oxides, chromium oxides, indium oxides and titanium oxides.
